(19) United States
(12) Patent Application Publication
(10) Pub. No.: US 2021/0257224 A1
(43) Pub. Date: Aug. 19, 2021

(54) METHOD FOR MANUFACTURING WIRING SUBSTRATE, AND WIRING SUBSTRATE

(71) Applicant: IBIDEN CO., LTD., Ogaki (JP)

(72) Inventors: Kazuhiko KURANOBU, Ogaki (JP); Tomoya DAIZO, Ogaki (JP)

(73) Assignee: IBIDEN CO., LTD., Ogaki (JP)

(21) Appl. No.: 17/159,619

(22) Filed: Jan. 27, 2021

(30) Foreign Application Priority Data
Feb. 14, 2020 (JP) 2020-023602

(51) Int. Cl. H01L 21/48; H01L 23/498

(52) U.S. Cl. CPC H01L 21/4857; H01L 23/49838; H01L 23/49822

(57) ABSTRACT

A manufacturing method of a wiring substrate includes forming an interlayer insulating layer on a substrate, forming a metal film on a surface of the insulating layer such that the metal film covers the surface of the insulating layer, etching a surface of the metal film on the opposite side with respect to the insulating layer such that the surface of the metal film is roughened, forming a dry film on the roughened surface of the metal film such that the dry film has an opening formed in the dry film, forming an electrolytic plating film in the opening using the metal film as a power feeding layer, removing the dry film from the metal film, and removing part of the metal film exposed from the plating film by the dry film removing such that the part of the metal film is removed from the surface of the insulating layer.

### CROSS-REFERENCE TO RELATED APPLICATIONS

The present application is based upon and claims the benefit of priority to Japanese Patent Application No. 2020-023602, filed Feb. 14, 2020, the entire contents of which are incorporated herein by reference.

### BACKGROUND OF THE INVENTION

### Field of the Invention

The present invention relates to a method for manufacturing a wiring substrate and relates to a wiring substrate.

### Description of Background Art

Japanese Patent Laid-Open Publication No. 2006-165094 describes a method for manufacturing a wiring substrate. In the manufacturing method of Japanese Patent Laid-Open Publication No. 2006-165094, an interior circuit is embedded and flattened using an insulating resin sheet, and the insulating resin is surface-roughened after heat curing. Then, after an electroless plating film is formed, a non-circuit forming part is protected using a plating resist, and a wiring pattern is formed by applying electrolytic plating. The entire contents of this publication are incorporated herein by reference.

### SUMMARY OF THE INVENTION

According to one aspect of the present invention, a manufacturing method of a wiring substrate includes forming an interlayer insulating layer on a substrate, forming a metal film on a surface of the interlayer insulating layer such that the metal film covers the surface of the interlayer insulating layer, etching a surface of the metal film on the opposite side with respect to the interlayer insulating layer such that the surface of the metal film is roughened on the opposite side with respect to the interlayer insulating layer, forming a dry film on the surface of the metal film roughened by the etching such that the dry film has an opening formed in the dry film, forming an electrolytic plating film in the opening of the dry film using the metal film as a power feeding layer, removing the dry film from the metal film formed on the surface of the interlayer insulating layer, and removing part of the metal film exposed from the electrolytic plating film by the removing of the dry film such that the part of the of the metal film is removed from the surface of the interlayer insulating layer.

According to another aspect of the present invention, a wiring substrate includes a substrate, an interlayer insulating layer formed on the substrate, a metal film formed on a surface of the interlayer insulating layer, and an electrolytic plating film formed on a surface of the metal film. The surface of the metal film is a roughed surface having a different profile from a roughness of the surface of the interlayer insulating layer.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a flowchart illustrating an example of a method for manufacturing a wiring substrate according to an embodiment of the present invention;

FIG. 2A is a cross-sectional view illustrating a process in the example of the method for manufacturing a wiring substrate according to the embodiment of the present invention;

FIG. 2B is a cross-sectional view illustrating a process in the example of the method for manufacturing a wiring substrate according to the embodiment of the present invention;

FIG. 2C is a cross-sectional view illustrating a process in the example of the method for manufacturing a wiring substrate according to the embodiment of the present invention;

FIG. 2D is a cross-sectional view illustrating a process in the example of the method for manufacturing a wiring substrate according to the embodiment of the present invention;

FIG. 2E is a cross-sectional view illustrating a process in the example of the method for manufacturing a wiring substrate according to the embodiment of the present invention;

FIG. 2F is a cross-sectional view illustrating a process in the example of the method for manufacturing a wiring substrate according to the embodiment of the present invention;

FIG. 2G is a cross-sectional view illustrating a process in the example of the method for manufacturing a wiring substrate according to the embodiment of the present invention;

FIG. 3A is a cross-sectional view of a state in which an interlayer insulating layer and a metal film are formed on a substrate in an atmospheric pressure atmosphere;

FIG. 3B is a cross-sectional view of a state in which a dry film is laminated on the interlayer insulating layer in an atmospheric pressure atmosphere;

FIG. 3C is a cross-sectional view of a state in which a pressure is applied from above the dry film in atmospheric pressure atmosphere after the state of FIG. 3B;

FIG. 3D is a cross-sectional view in atmospheric pressure atmosphere of a state in which, after the application of the pressure illustrated in FIG. 3C, the pressure is removed;

FIG. 4A is an SEM photograph of a surface of the metal film that has been subjected to a surface roughening treatment; and

FIG. 4B is an SEM photograph of a surface of the metal film that has not been subjected to a surface roughening treatment.

### DETAILED DESCRIPTION OF THE EMBODIMENTS

Embodiments will now be described with reference to the accompanying drawings, wherein like reference numerals designate corresponding or identical elements throughout the various drawings.

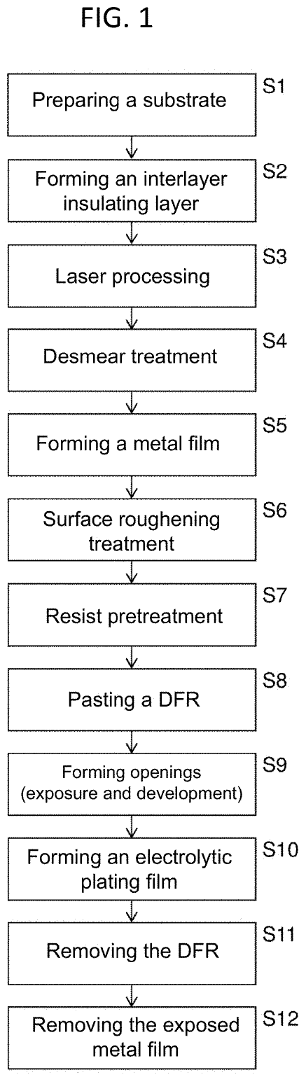

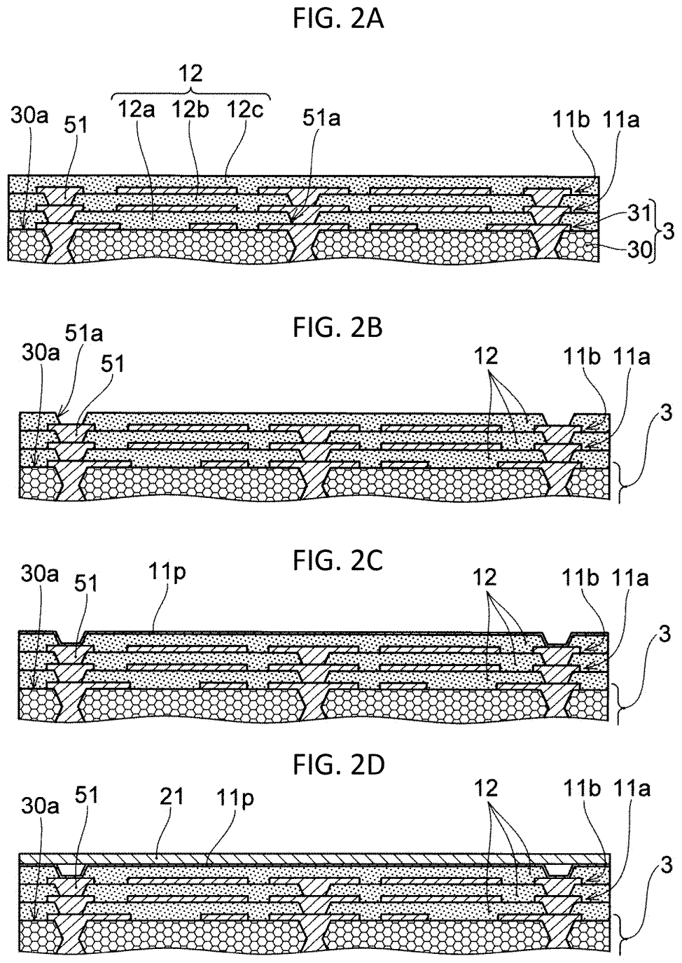

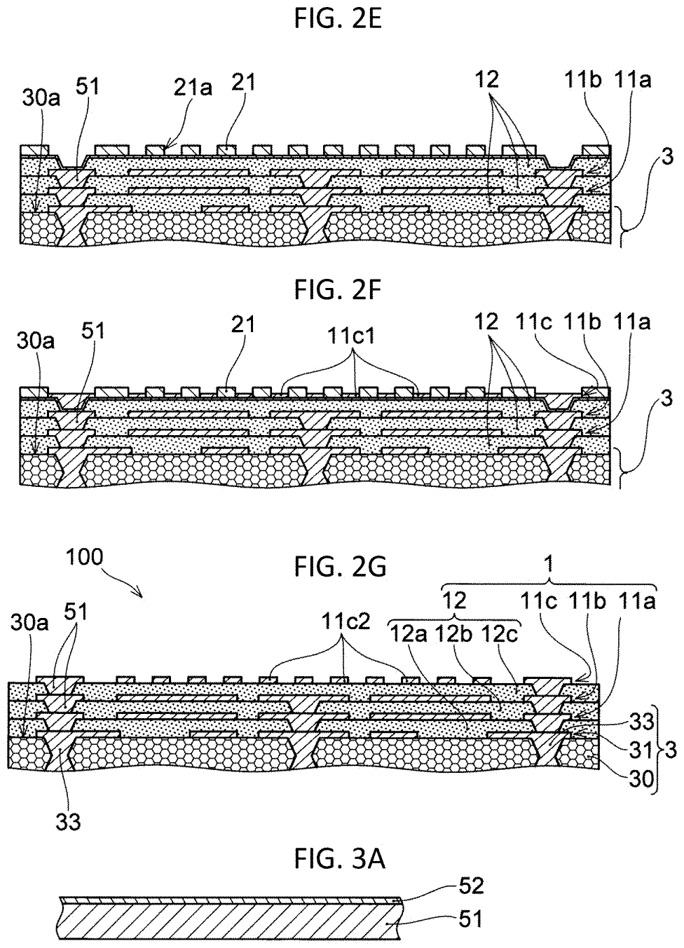

A method for manufacturing a wiring substrate according to an embodiment of the present invention is described with reference to the drawings. FIG. 1 is a flowchart illustrating an example of main parts of a method for manufacturing a wiring substrate according to an embodiment of the present invention. FIGS. 2A-2G illustrate cross-sectional views of processes of the method.

As illustrated in FIGS. 1 and 2A-2G, the manufacturing method of the present embodiment includes: preparing a substrate (core substrate) 3 (S1); forming an interlayer insulating layer 12 on the substrate 3 (S2, FIG. 2A); forming a metal film (11p) on a substantially entire surface of the interlayer insulating layer 12 (S5, FIG. 2C); laminating a dry film 21 on the metal film (11p) (S8, FIG. 2D); forming openings (21a) in the dry film 21 (S9, FIG. 2E); forming an electrolytic plating film (11c1) in the openings (21a) using the metal film (11p) as a power feeding layer (S10, FIG. 2F); removing the dry film 21 (S11, FIG. 2G); and removing the metal film (11p) that is exposed due to that the electrolytic plating film (11c1) is not formed (S12, FIG. 2G). The manufacturing method of the present embodiment further includes roughening a surface of the metal film (11p) by etching (S6) before laminating the dry film 21 (S8).

In the example of FIGS. 2A-2G, three interlayer insulating layers 12 are formed on a first surface (30a) of the core substrate 3. A metal film (11p) and an electrolytic plating film (11c1) (conductor layer) of the present embodiment can be formed on any one of the interlayer insulating layers 12. Here, an example is described in which it is applied to an outermost conductor layer (11c), farthest from the core substrate 3, where a particularly fine pattern is likely to be required. However, a conductor layer formed by the metal film (11p) and the electrolytic plating film (11c1) is not limited to the outermost conductor layer. Further, a similar conductor layer can also be formed on a surface of the core substrate 3 on an opposite side with respect to the first surface (30a).

Along with reduction in size and reduction in thickness of electronic devices, reduction in thickness and increase in density are demanded for a wiring substrate. For example, along with increase in density, widths and spacings of wirings or pads formed in an outermost layer of a wiring substrate may each be set to about 10 μm. For example, a semi-additive method is used for the formation of such a fine pattern.

In a semi-additive method, for example, a photosensitive dry film is provided on a surface of a metal film formed on an insulating layer, and a resist film (mask film) is formed by forming openings by exposure and development (hereinafter, both a dry film and a resist film (dry film resist) formed using the dry film are referred to as “DFR”). However, when wiring widths and spacings of wiring patterns are, for example, about 10 μm, a short-circuit defect or the like may occur between adjacent wrings or pads.

One possible cause for a short-circuit defect is the presence of air bubbles at an interface between a metal film and a DFR. When an opening of a DFR is formed at a portion of an air bubble, the opening and the air bubble are communicatingly connected to each other, and, when an electrolytic plating film is formed, a plating solution may also infiltrate into the air bubble to form a plating film. As a result, when spacings between openings are narrow, a short circuit may occur between patterns formed in adjacent openings.

Entrainment of air bubbles at an interface between a metal film and a DFR can be suppressed by sequentially pressurizing the DFR from a center toward edges thereof when the DFR is laminated on the metal film. However, air bubbles may still be included at the interface. In this regard, by roughening a surface of the metal film, entrainment of air bubbles can be reduced. It is thought that, even when a gas such as air is once sandwiched at an interface between a metal film and a DFR, the gas can easily escape to the outside of the interface through recesses of a rough surface, and thus, air bubbles are unlikely to remain at the interface.

Since a metal film is very thin, for example, having a thickness of about 0.5 μm, a surface of the metal film follows a surface of an insulating layer as a base, and as a result, unevenness of the surface of the insulating layer may also appear on the surface of the metal film. Therefore, it is thought that, by roughening a surface of an insulating film for forming a metal film, a rough surface having the same roughness can be obtained for a surface of the metal film on which a DFR is laminated.

However, when a surface of an insulating film for forming a metal film becomes a rough surface, the metal film may penetrate deep into recesses of the rough surface. In this case, in patterning of a conductor layer including the metal film, when unwanted portions of the metal film are removed by etching, it may take a long time. In that case, not only the number of man-hours is increased, but also a portion of the metal film that should remain as a desired wiring pattern may be excessively etched. In addition, it may be preferable for a wiring substrate to have an electrical characteristic such as a low dielectric loss tangent (Df: tan δ) that results in a decrease in loss at a high frequency. However, an increase in the surface roughness of the insulating layer may lead to an increase in the dielectric loss tangent. Therefore, it may not be possible to make a surface of an insulating film for forming a metal film a rough surface having a sufficient roughness for suppressing an air bubble.

Therefore, in the present embodiment, a surface of an interlayer insulating layer 12 (formation surface for a metal film (11p)) is not made very rough. However, for the metal film (11p) formed on the surface of the interlayer insulating layer 12, a surface of the metal film (11p) on which a DFR 21 is laminated is roughened. For example, a surface of a metal film (11p) on which a DFR is formed is roughened to have an arithmetic average roughness (Ra) of about 0.2 μm or more and 1.0 μm or less.

On the other hand, a surface of an interlayer insulating layer 12 can have a surface roughness of about 0.1 μm or more and 0.4 μm or less, for example, about 0.11 μm in arithmetic average roughness (Ra). Or, a surface of an interlayer insulating layer 12 can be roughened so as to have such a surface roughness. When a surface of each of a metal film (11p) and an interlayer insulating layer 12 has the above surface roughness, it is thought that air bubbles are unlikely to occur or remain between a DFR 53 and a metal film 52, and a problem such as an increase in etching time of the metal film (11p) or an increase in dielectric loss tangent is unlikely to occur.

The metal film (11p) is very thin (for example, has a thickness of about 0.5 μm). Therefore, for example, by surface-roughening the metal film (11p) by etching or the like, a portion where the metal film (11p) is locally removed entirely in its thickness direction can occur. Even when a crack or the like is formed in this way, since the portion where the crack or the like is formed is a part of the surface of the metal film (11p), a problem such as an increase in the electrical resistance of the metal film (11p) due to the crack or the like does not occur.

Using a conventional method for laminating a DFR to an interlayer insulating film as an example, entrainment of air bubbles is further described with reference to the drawings. A case of laminating a DFR in an atmospheric pressure atmosphere (normal pressure: it means an atmosphere that is not particularly pressurized or depressurized, and it does not necessarily have to be 1 atm; the same applies hereinafter) is described.

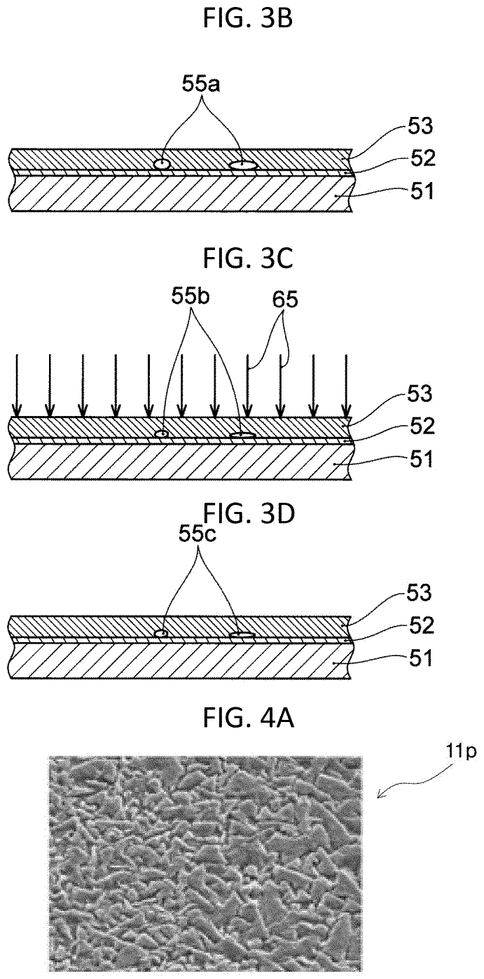

FIGS. 3A-3D illustrate processes in which an interlayer insulating layer 51 and a metal film 52 are formed on a substrate (not illustrated in the drawings) and a DFR 53 is laminated on a surface thereof. FIGS. 3A-3D illustrate a case where a process of laminating the DFR 53 (a process of laminating a DFR and a process of applying a pressure for causing a tight adhesion) is conducted in an atmospheric pressure (normal pressure) atmosphere.

That is, FIG. 3A illustrates a state in which the substrate on which the interlayer insulating layer 51 and the metal film 52 are formed is preheated to about 50° C. in an atmospheric pressure atmosphere. The preheating is a pretreatment for laminating the DFR 53. Therefore, the preheat treatment (FIG. 3A) is applied in an atmospheric pressure atmosphere.

FIG. 3B illustrates a state in which the DFR 53 has been supplied to the surface of the metal film 52. In this case, as illustrated in FIG. 3B, air bubbles (55a) may be formed between the metal film 52 and the DFR 53.

Next, as illustrated in FIG. 3C, in order to cause the DFR 53 to tightly adhere to the metal film 52, a lamination pressure of 65 (for example, 0.5 MPa) is applied from a surface of the DFR 53 while a temperature (laminate temperature) of the substrate is raised to, for example, about 115° C. The air bubbles (55a) are diffused and become slightly smaller air bubbles (55b), and the DFR 53 tightly adheres to the metal film 52. The application of the pressure is illustrated in FIG. 3C as that a uniform pressure is applied to the entire surface all at once. However, in fact, as described above, the pressure is applied while a site of the application is shifted from a center portion toward edge sides of the DFR 53. In this case, as illustrated in FIG. 3C, the air bubbles (55a) diffuse into base anchors and the DFR. However, the air bubbles (55a) cannot be completely absorbed and remain as slightly smaller air bubbles (55b).

Next, as illustrated in FIG. 3D, the lamination pressure is removed. However, air bubbles (55c) can remain in the DFR 53 or the like.

Therefore, it is preferable that the DFR 53 can be laminated to the metal film 52 without causing the air bubbles (55c) even in an atmospheric pressure atmosphere. As described above, in the present embodiment, since the surface of the metal film 52 is roughened, air bubbles can easily diffuse or move, for example, through the recesses of the roughened surface, and the air bubbles can easily disappear. As a result, it is thought that occurrence of defects during pattern formation in the wiring substrate can be suppressed.

The metal film 52 corresponds to the metal film (11p) (see FIG. 2C) in the manufacturing method of the present embodiment. The metal film (11p) (metal film 52) is formed using, for example, an electroless plating method, a vacuum deposition method, a sputtering method, or the like. As the metal film (11p), for example, a plating film, a vapor-deposited film, or the like, of copper, nickel or the like, is formed to have a thickness of about 0.4-0.8 μm.

As a method for surface-roughening the metal film (11p), a commercially available etching solution using an organic acid-based microetching agent is exemplified. By such an etching process, the surface of the metal film (11p) is roughened to have an arithmetic average roughness (Ra) of, for example, about 0.2 μm or more and 1.0 μm or less. As a pretreatment for this etching process, a treatment with a commercially available pretreatment agent may be applied. That is, it is possible that substances that hinder a roughening ability, such as fingerprints, oxides, or the like, can be reliably removed, and more uniform roughening can be achieved.

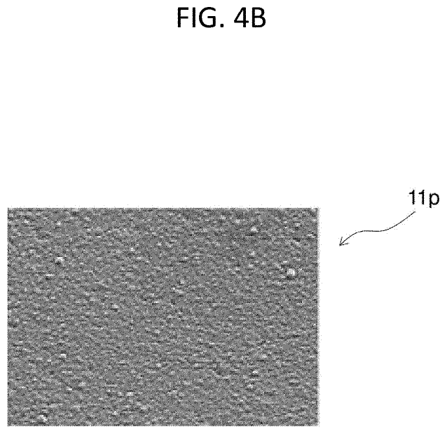

FIG. 4A shows an observation photograph of a surface of a flat portion of the roughened metal film (11p) taken with a scanning electron microscope (hereinafter referred to as SEM) at 5000×, and FIG. 4B shows an observation photograph of a surface of the unroughened metal film (11p) taken using the same method. As is clear from FIG. 4A, the surface of the metal film (11p) produced using the manufacturing method of the present embodiment is very uneven (for example, having an arithmetic average roughness (Ra) of about 0.2 μm or more and 1.0 μm or less). As a result, even when air bubbles are entrained between the DFR 21 (see FIG. 2D) and the metal film (11p), the air bubbles diffuse, for example, via the recesses of the uneven surface, and the DFR 21 and the metal film (11p) tightly adhere to each other without air bubbles interposed therebetween.

Due to the above-described surface roughening treatment, a through part such as a crack described above may be formed in a part of the metal film (11p). In the through part of the metal film (11p), the interlayer insulating layer 12 is exposed. As described above, such a through part such as a crack is formed in a small or short range, that is, it is formed only in a small part of the metal film (11p), and thus, a problem such as an increase in electrical resistance is unlikely to occur. Since air can escape from a crack or the like to the outside, the formation of a crack or the like may be preferable. No crack was observed at bottoms of via holes (51a).

An example of the method for manufacturing the wiring substrate of the present embodiment is described in detail again with reference to the flowchart of FIG. 1 and FIGS. 2A-2G.

As illustrated in FIGS. 1 and 2A, the substrate (core substrate) 3 is prepared (S1), and the interlayer insulating layers 12 are formed on the first surface (30a) of the core substrate 3 (S2). In the core substrate 3, a core substrate conductor layer 31 is formed on a first surface (30a) of a core insulating layer 30 formed of an insulating resin containing a reinforcing material formed of a glass fibers or the like. For example, the core substrate conductor layer 31 is formed by patterning a metal foil of a copper-clad laminated plate.

A first interlayer insulating layer (12a) is formed on the first surface (30a) of the core insulating layer 30 and on the core substrate conductor layer 31. Further, a first conductor layer (11a) is formed on the first interlayer insulating layer (12a). In the formation of the first conductor layer (11a), via conductors 51 are formed in the first interlayer insulating layer (12a). The first interlayer insulating layer (12a) is formed, for example, by laminating a prepreg, which contains a semi-cured epoxy resin and a reinforcing material such as a glass fiber, and a film-like epoxy resin (hereinafter, simply referred to as a “resin film”) on the first surface (30a) of the core substrate 3, and thermocompression bonding them. After that, for example, by irradiation with a carbon dioxide laser, the via holes (51a) for forming the via conductors 51 are formed in the first interlayer insulating layer (12a).

A second interlayer insulating layer (12b), a third interlayer insulating layer (12c), and a second conductor layer (11b) are formed using the same method for the first interlayer insulating layer (12a) or the first conductor layer (11a). For the formation of the first conductor layer (11a) and the second conductor layer (11b), the method for forming the third conductor layer (11c) using a semi-additive method described below can be applied. That is, after the thermal compression bonding of the resin film and the like, the first and second conductor layers (11a, 11b) including desired conductor patterns, and the via conductors 51, are formed, for example, using a semi-additive method including pattern plating. The third interlayer insulating layer (12c) (interlayer insulating layer 12) is exposed as an outermost layer on the first surface (30a) side of the core substrate 3.

Next, as illustrated in FIG. 2B, the via holes (51a) exposing the second conductor layer (11b) are formed in the outermost interlayer insulating layer 12 by, for example, laser processing (S3 of FIG. 1). The via holes (51a) are formed by irradiation with carbon dioxide laser or the like. After that, in order to remove organic residues (smears) adhering to the bottoms of the via holes (51a), for example, the surface of the outermost interlayer insulating layer 12 is subjected to a treatment (desmear treatment) with a chemical solution such as a permanganate acid (S4 of FIG. 1). The desmear treatment is applied, for example, by a plasma treatment using a parallel plate plasma cleaning device. As a result, the smears are removed and an uneven surface is formed on the surface of the interlayer insulating layer 12. However, as described above, when unevenness with large height differences is formed on the surface of the interlayer insulating layer 12, time of a post-process may increase and a dielectric loss tangent may increase. Therefore, the surface of the interlayer insulating layer 12 is treated so as to have an arithmetic average roughness (Ra) of, for example, about 0.1 μm or more and 0.4 μm or less as described above.

As illustrated in FIG. 2C, the metal film (11p) is formed by electroless plating or the like on the substantially entire surface of the interlayer insulating layer 12, including the interiors of the via holes (51a), as a plating base film which is formed of copper and is used as a power feeding layer for electrolytic plating in the next process (S5 of FIG. 1). It is also possible that the metal film (11p) is formed by vacuum deposition or sputtering.

After that, a surface roughening treatment (organic acid treatment) of the surface of the metal film (11p) is applied (S6 of FIG. 1). Due to the surface roughening treatment, as described above, unevenness is formed on the surface of the metal film (11p) and air bubbles can easily escape. For example, as the surface roughening treatment, etching is applied using an organic acid-based microetching agent. As a result, the surface of the metal film (11p) is roughened to have a surface roughness of, for example, about 0.2 μm or more and 1.0 μm or less in arithmetic average roughness (Ra).

After that, the surface of the metal film (11p) is subjected to a resist pretreatment (S7 of FIG. 1). Impurities are removed from the surface of the metal film (11p) by the resist pretreatment. For example, the surface of the metal film (11p) is cleaned with a 10% aqueous sulfuric acid solution. Then, as illustrated in FIG. 2D, the dry film (DFR) 21 is laminated on the metal film (11p) (S8 of FIG. 1). For DFR 21, for example, a photosensitive film is used.

As illustrated in FIG. 2E, the DFR 21 is exposed and developed to have desired patterns, and the openings (21a) are formed (S9 of FIG. 1).

As illustrated in FIG. 2F, by immersing the core substrate 3 in an electrolytic plating solution and applying an electric current using the metal film (11p) as a power feeding layer, the electrolytic plating film (11c1) is formed in the openings (21a) of the DFR 21 (S10 of FIG. 1).

As illustrated in FIG. 2G, the DFR 21 is removed (S11 of FIG. 1), and the metal film (11p) exposed by the removal of the DFR 21 is removed (S12 of FIG. 1). The third conductor layer (11c) including desired conductor patterns is formed. Component mounting pads (11c2) are formed in the third conductor layer (11c). Terminals of an external component such as a semiconductor integrated circuit device (not illustrated in the drawings) can be connected to the component mounting pads (11c2). On the first surface (30a) of the core substrate 3, a first build-up layer 1 including the conductor layers and the interlayer insulating layers is formed. Through the above processes, the wiring substrate 100 is completed.

A solder resist layer (not illustrated in the drawings) may be formed on the surface of the wiring substrate 100 of FIG. 2G. For example, a resin film (not illustrated in the drawings) containing a photosensitive epoxy resin or a polyimide resin is formed using a method such as laminating a resin film or applying a liquid resin. Openings exposing predetermined regions (the component mounting pads (11c2) and the like) of the third conductor layer (11c) are provided in the resin film by subjecting the resin film to exposure and development using a mask having an appropriate pattern.

On each of the component mounting pads (11c2), a surface protection film (not illustrated in the drawings) formed of Au, Ni/Au, Ni/Pd/Au, solder, heat-resistant preflux, or the like may be formed by electroless plating, solder leveling, spray coating, or the like.

The wiring substrate 100 illustrated in FIG. 2G is also an example of a wiring substrate of another embodiment of the present invention. The wiring substrate 100 includes the core substrate 3 and the first build-up layer 1. The core substrate 3 includes: the core insulating layer 30 having the first surface (30a) and a second surface (not illustrated in the drawings) on an opposite side with respect to the first surface (30a); and the core substrate conductor layer 31 provided on the first surface (30a). In the example of FIG. 2G, a build-up layer and the like formed on the second surface side are omitted. However, on the second surface side, a build-up layer having a structure same as or different from that of the first build-up layer 1 may be formed. The first build-up layer 1 is provided on the first surface (30a) of the core insulating layer 30, that is, on the first surface (30a) side with respect to the core substrate 3. The first build-up layer 1 includes three interlayer insulating layers 12 (the first interlayer insulating layer (12a), the second interlayer insulating layer (12b), and the third interlayer insulating layer (12c)) and three conductor layers (the first conductor layer (11a), the second conductor layer (11b), and the third conductor layer (11c)) that are alternately laminated. The first build-up layer 1 is not limited to having three pairs of insulating layers and conductor layers as in the example of FIG. 2G, but may include any number (equal to or larger than one) of pairs of insulating layers and conductor layers. In the following description, when it is not necessary to distinguish between the first interlayer insulating layer (12a), the second interlayer insulating layer (12b), and the third interlayer insulating layer (12c), all the first-third interlayer insulating layers (12a, 12b, 12c) are also referred to as the interlayer insulating layers 12.

In the description of the wiring substrate 100, a side farther from the core insulating layer 30 in a thickness direction of the wiring substrate 100 is also referred to as an “upper side” or simply “upper,” and a side closer to the core insulating layer 30 is also referred to as a “lower side” or simply “lower.” Further, for the conductor layers and the interlayer insulating layers, a surface facing an opposite side with respect to the core insulating layer 30 is also referred to as an “upper surface,” and a surface facing the core insulating layer 30 side is also referred to as a “lower surface.”

In the wiring substrate 100 of FIG. 2G, on the exposed surface of the first surface (30a) of the core insulating layer 30 and on the core substrate conductor layer 31, the innermost first insulating layer (12a) of the three interlayer insulating layers 12 is laminated. On the first interlayer insulating layer (12a), further, the first conductor layer (11a), the middle-layer second interlayer insulating layer (12b), the second conductor layer (11b), the outermost third interlayer insulating layer (12c) on the first surface (30a), and the outermost third conductor layer (11c) on the first surface (30a) side are laminated in this order. For the formation of any one of these three conductor layers, the series of processes in the manufacturing method of the embodiment, including the roughening of the surface of the metal film (11p) (see FIG. 2D), can be applied.

The core substrate conductor layer 31 can be formed, for example, by a metal foil, a vapor-deposited film, or a plating film, containing copper, nickel, silver, or the like, alone or a laminate of these. The third conductor layer (11a) can include the metal film (11p) (see FIG. 2D) and the electrolytic plating film (11c1) (see FIG. 2F). The metal film (11p) is formed, for example, by electrolytic plating or sputtering of copper. The electrolytic plating film (11c1) is, for example, a plating film formed of copper, nickel, or like. The first and second conductor layers (11, 12) also can each include a metal film and an electrolytic plating film same as the metal film (11p) and the electrolytic plating film (11c1).

The conductor layers (the core substrate conductor layer 31 and the first-third conductor layers (11a-11c)) can each have any thickness. The conductor layers can each have a thickness of, for example, 5 μm or more and 30 μm or less. Further, the conductor layers may have thicknesses different from each other.

The insulating layers (the core insulating layer 30 and the interlayer insulating layers 12) are each formed of any insulating resin. Examples of the insulating resin include an epoxy resin, a bismaleimide triazine resin (BT resin), a phenol resin, and the like. The insulating layers formed using these insulating resins may each contain inorganic filler such as silica. Further, the insulating layers may each contain a reinforcing material (not illustrated in the drawings) formed of a glass fiber, an aramid fiber, a glass non-woven fabric, an aramid non-woven fabric, or the like so as to have an appropriate rigidity.

The interlayer insulating layers can each have any thickness. For example, the core insulating layer 30 can have a thickness of about 20 μm or more and 500 μm or less. On the other hand, the interlayer insulating layers 12 can each have a thickness of about 15 μm or more and 100 μm or less. In the wiring substrate 100 of the example of FIG. 2G, the interlayer insulating layers 12 have substantially the same thickness. However, the interlayer insulating layers 12 can have thicknesses different from each other.

The via conductors 51 are formed in the interlayer insulating layers 12. Further, through-hole conductors 33 are formed in the core insulating layer 30. Each of the via conductors 51 and the through-hole conductors 33 electrically connects conductor layers sandwiching the insulating layer containing the conductor itself. In the example of FIG. 2G, the via conductors 51 each have a tapered shape that is reduced in outer diameter (width) toward the core substrate 3. Further, the through-hole conductors 33 each have an outer diameter (width) that decreases from both the first surface (30a) side and the second surface side (not illustrated in the drawings) toward a center part of the core substrate 3 in the thickness direction, and each have a constriction in the center part in the thickness direction.

Each of the via conductors 51 is integrally formed with the conductor layer on an upper side of the conductor by any metal such as copper or nickel, and can include an electroless plating film or a vapor-deposited film, and an electrolytic plating film. Each of the through-hole conductors 33 is integrally formed with the core substrate conductor layer 31 by any metal such as copper or nickel, and can include an electroless plating film or a vapor-deposited film, and an electrolytic plating film.

The conductor layers can each include any desired conductor patterns. In the wiring substrate 100 of FIG. 2G, the third conductor layer (11c) which is the outermost conductor layer of the first build-up layer 1 includes the component mounting pads (11c2) on which an external element such as an external electrical component is mounted.

As illustrated in FIG. 2G, the wiring substrate 100 of the present embodiment includes a substrate (for example, the core substrate 3, or a laminate of the conductor layers and the interlayer insulating layers in the first build-up layer 1), an interlayer insulating layer 12 (for example, the third interlayer insulating layer (12c)), a metal film (for example, the metal film (11p) of FIG. 2D), and an electrolytic plating film (for example, the electrolytic plating film (11c1) of FIG. 2F). The interlayer insulating layer 12 is formed on a first surface of the substrate (for example, the first surface (30a) of the core insulating layer 30). The metal film exemplified by the metal film (11p) is formed on the interlayer insulating layer 12. The electrolytic plating film exemplified by the electrolytic plating film (11c1) is formed, for example, on the metal film (11p). Then, a surface of the metal film (11p) facing the electrolytic plating film (11c1) is a rough surface having a shape different from a rough surface of a surface of the interlayer insulating layer 12 facing the metal film (11p).

Here, “a rough surface having a different shape” does not mean a rough surface that is formed by following the unevenness of the surface of the lower layer (the interlayer insulating layer 12), but means a rough surface that is formed independently of the surface (rough surface) of the lower layer and, as a result, has a surface profile different from that of the surface of the lower layer. For example, when a thin metal film (11p) having a submicron thickness is simply formed on the surface of the interlayer insulating layer 12 by electroless plating or the like, the surface of the metal film (11p) can have unevenness that inherits the unevenness of the surface of the interlayer insulating layer 12. However, in the wiring substrate 100 of the present embodiment, for example, as a result of a surface roughening treatment by etching or the like, the metal film (11p) has, as a surface on the electrolytic plating film (11c1) side, a rough surface different in size of unevenness or in shape of undulation from the surface of the interlayer insulating layer 12.

Further, a through part reaching from the surface of the metal film (11p) facing the electrolytic plating film (11c1) to the interlayer insulating layer 12 may be formed in the metal film (11p). For example, by forming a through part such as a crack, it is thought that, when the DFR is laminated to the surface of the metal film (11p), air bubbles can easily escape.

Further, the arithmetic average roughness (Ra) of the surface of the metal film (11p) facing the electrolytic plating film (11c1) may be larger than the arithmetic average roughness (Ra) of the surface of the interlayer insulating layer 12 facing the metal film (11p). It is possible that unwanted portions of the metal film (11p) can be easily removed. Further, it is possible that the wiring substrate 100 can have excellent characteristics for high frequency transmission. Further, in the wiring substrate 100, a short circuit defect is unlikely to occur, and a high reliability can be obtained.

Specifically, the arithmetic average roughness (Ra) of the surface of the metal film (11p) facing the electrolytic plating film (11c1) may be 0.2 μm or more and 1.0 μm or less, and the surface roughness of the surface of the interlayer insulating layer 12 facing the metal film (11p) may be 0.1 μm or more and 0.4 μm or less in arithmetic average roughness (Ra).

According to a method for manufacturing a wiring substrate according to an embodiment of the present invention, when wiring patterns are formed using a semi-additive method, since a surface of a metal film, which is a power feeding layer for an electrolytic plating film, is roughened, air bubbles are unlikely to be entrained during laminating of a DFR. Therefore, it is also possible that laminating of a DFR can be conducted in an atmospheric pressure atmosphere. Therefore, a wiring substrate can be manufactured with inexpensive equipment. Further, it is possible that, since man-hours can be reduced, the cost of the wiring substrate can be reduced. Since air bubbles are unlikely to be formed between a DFR and a metal film, a short-circuit defect is unlikely to occur even when a fine wiring pattern is formed. Therefore, it is thought that the quality of the wiring substrate can be improved.

In the manufacturing method of Japanese Patent Laid-Open Publication No. 2006-165094, it is thought that air bubbles (voids) are likely to be entrained between the plating resist and the electroless plating film. When air bubbles are formed under a resin film, poor pattern formation such as a short circuit between adjacent pads is likely to occur.

A manufacturing method of a wiring substrate according to an embodiment of the present invention includes: preparing a substrate; forming an interlayer insulating layer on the substrate; forming a metal film on a substantially entire surface of the interlayer insulating layer; laminating a dry film on the metal film; forming an opening in the dry film; forming an electrolytic plating film in the opening using the metal film as a power feeding layer; removing the dry film; and removing the metal film that is exposed due to that the electrolytic plating film is not formed. The manufacturing method further includes, before the laminating of the dry film, roughening a surface of the metal film on an opposite side with respect to the interlayer insulating layer by etching.

A wiring substrate according to an embodiment of the present invention includes: a substrate; an interlayer insulating layer formed on the substrate; a metal film formed on the interlayer insulating layer; and an electrolytic plating film formed on the metal film. A surface of the metal film facing the electrolytic plating film is a rough surface having a shape different from a rough surface of a surface of the interlayer insulating layer facing the metal film.

According to an embodiment of the present invention, it is thought that air bubbles entrained when the dry film is laminated on the metal film can easily escape. Further, since the dry film and the metal film are likely to tightly adhere to each other, it is thought that poor pattern formation is suppressed.

Obviously, numerous modifications and variations of the present invention are possible in light of the above teachings. It is therefore to be understood that within the scope of the appended claims, the invention may be practiced otherwise than as specifically described herein.

What is claimed is:

1. A manufacturing method of a wiring substrate, comprising:
forming an interlayer insulating layer on a substrate;
forming a metal film on a surface of the interlayer insulating layer such that the metal film covers the surface of the interlayer insulating layer;
etching a surface of the metal film on an opposite side with respect to the interlayer insulating layer such that the surface of the metal film is roughened on the opposite side with respect to the interlayer insulating layer;
forming a dry film on the surface of the metal film roughened by the etching such that the dry film has an opening formed in the dry film;
forming an electrolytic plating film in the opening of the dry film using the metal film as a power feeding layer;
removing the dry film from the metal film formed on the surface of the interlayer insulating layer; and
removing part of the metal film exposed from the electrolytic plating film by the removing of the dry film such that the part of the of the metal film is removed from the surface of the interlayer insulating layer.

2. The manufacturing method according to claim 1, wherein the forming of the dry film includes laminating the dry film on the surface of the metal film in an atmospheric pressure atmosphere.

3. The manufacturing method according to claim 1, further comprising:
roughening the surface of the interlayer insulating layer before the forming of the metal film.

4. The manufacturing method according to claim 1, wherein the etching of the surface of the metal film includes forming through part in the metal film such that the through part reaches from the surface of the metal film to the interlayer insulating layer.

5. The manufacturing method according to claim 1, wherein the etching of the metal film includes applying an organic acid-based microetching agent on the surface of the metal film.

6. The manufacturing method according to claim 1, wherein the surface of the metal film is etched such that an arithmetic average roughness Ra of the surface of the metal film facing the electrolytic plating film is larger than an arithmetic average roughness Ra of a surface of the interlayer insulating layer facing the metal film.

7. The manufacturing method according to claim 6, wherein the surface of the interlayer insulating layer has the arithmetic average roughness Ra in a range of 0.1 μm to 0.4 μm or less, and the surface of the metal film is etched such that the arithmetic average roughness Ra of the surface of the metal film is in a range of 0.2 μm to 1.0 μm.

8. The manufacturing method according to claim 1, wherein the forming of the metal film comprises applying electroless plating on the surface of the interlayer insulating layer.

9. The manufacturing method according to claim 1, wherein the dry film is a photosensitive film, and the forming of the dry film includes patterning the dry film by exposure and development such that the opening is formed in the dry film.

10. The manufacturing method according to claim 1, wherein the forming of the dry film includes laminating the dry film on the surface of the metal film, and forming the opening in the dry film.

11. The manufacturing method according to claim 10, wherein the dry film is laminated on the surface of the metal film in an atmospheric pressure atmosphere.

12. The manufacturing method according to claim 10, further comprising:
roughening the surface of the interlayer insulating layer before the forming of the metal film.

13. The manufacturing method according to claim 10, wherein the etching of the surface of the metal film includes forming through part in the metal film such that the through part reaches from the surface of the metal film to the interlayer insulating layer.

14. The manufacturing method according to claim 10, wherein the etching of the metal film includes applying an organic acid-based microetching agent on the surface of the metal film.

15. The manufacturing method according to claim 10, wherein the surface of the metal film is etched such that an arithmetic average roughness Ra of the surface of the metal film facing the electrolytic plating film is larger than an arithmetic average roughness Ra of a surface of the interlayer insulating layer facing the metal film.

16. The manufacturing method according to claim 15, wherein the surface of the interlayer insulating layer has the arithmetic average roughness Ra in a range of 0.1 μm to 0.4 μm or less, and the surface of the metal film is etched such that the arithmetic average roughness Ra of the surface of the metal film is in a range of 0.2 μm to 1.0 μm.

17. A wiring substrate, comprising:
a substrate;
an interlayer insulating layer formed on the substrate;
a metal film formed on a surface of the interlayer insulating layer; and
an electrolytic plating film formed on a surface of the metal film,
wherein the surface of the metal film is a roughened surface having a different profile from a roughness of the surface of the interlayer insulating layer.

18. The wiring substrate according to claim 17, wherein the metal film has through part reaching from the surface of the metal film to the interlayer insulating layer.

19. The wiring substrate according to claim 17, wherein the metal film is formed such that an arithmetic average roughness Ra of the surface of the metal film is larger than an arithmetic average roughness Ra of the surface of the interlayer insulating layer.

20. The wiring substrate according to claim 19, wherein the metal film is formed such that the arithmetic average roughness Ra of the surface of the metal film is in the range of 0.2 μm to 1.0 μm, and the arithmetic average roughness Ra of the surface of the interlayer insulating layer is in a range of 0.1 μm to 0.4 μm.
